(19) United States
(12) Patent Application Publication
(10) Pub. No.: US 2023/0411324 A1
(43) Pub. Date: Dec. 21, 2023

(54) DISPLAY DEVICE AND DRIVER

(71) Applicant: Sharp Display Technology Corporation, Kameyama City (JP)

(72) Inventor: Shinzoh MURAKAMI, Kameyama City (JP)

(73) Assignee: Sharp Display Technology Corporation, Kameyama City (JP)

(21) Appl. No.: 18/208,888

(22) Filed: Jun. 13, 2023

(30) Foreign Application Priority Data
Jun. 17, 2022 (JP) 2022-097973

(51) Int. Cl. H01L 23/00; G02F 1/1345

(52) U.S. Cl. CPC H01L 24/06; H01L 24/05; G02F 1/13452; H01L 2224/05553; H01L 2224/0603; H01L 2224/2929; H01L 24/29; H01L 24/32; H01L 2224/32145; H01L 2224/05558; H01L 2224/05572; H01L 2224/05568; H01L 2224/06153; H01L 2224/06155

(57) ABSTRACT

A display device includes a display panel, a driver 12 including a first side part, a first terminal, a first wire connected to the first terminal, a second terminal located further away from a display area than the first terminal and closer to an end of the first side part than the first terminal, a second wire connected to the second terminal, a first bump disposed to overlap the first terminal, a second bump disposed to overlap the second terminal, and a third bump located closer to the display area than the second bump and closer to the end of the first side part than the first bump. The second wire is extended out from the second terminal toward the end of the first side part, and the third bump has an oblong shape in planar view and has a longitudinal direction parallel with an inclined portion.

### BACKGROUND

### 1. Field

The present disclosure relates to a display device and a driver.

### 2. Description of the Related Art

There has been known an example of a conventional display device described in International Publication No. 2010/024015. In International Publication No. 2010/024015, a semiconductor element is disclosed as the driver. The semiconductor element, which is provided in a display device described in International Publication No. 2010/024015, is mounted in a display panel including a display unit. The semiconductor element includes a rectangular principal surface having two long sides and two short sides and a plurality of output terminals provided on the principal surface, arrayed in a direction along the long sides, and electrically connected to the display unit of the display panel. The plurality of output terminals include a plurality of first terminals placed close to the centers of the long sides and a plurality of second terminals placed close to ends of the long sides. At least the first terminals of the plurality of output terminals are placed close to a first one of the two long sides, and at least some of the second terminals are located closer to a second one of the two long sides than the first terminals.

In the semiconductor element provided in the display device described in display device described in International Publication No. 2010/024015, the plurality of first terminals are arrayed parallel to the long sides, whereas the plurality of second terminals are arrayed so as to be located gradually closer to the second long side from the center of the first long side toward the ends of the first long side. With the first terminals and the second terminals arrayed in this way, no first terminals or second terminals are placed near either end of the first long side of the semiconductor element. This makes it easy for deformation such as warpage to occur near either end of the first long side of the semiconductor element when the semiconductor element is thermocompression bonded to the display panel via an ACF (anisotropic conductive film). Such deformation may be suppressed by placing, near both ends of the first long side, bumps projecting from the semiconductor element toward the display panel, as in the case of the first terminals and the second terminals. However, such placement of the bumps needs such consideration that wires connected to the second terminals do not interfere with the bumps when the wires are routed. This tends to cause the wires to be routed in a larger space, undesirably resulting in widening of the frame width of the display panel.

It is desirable to achieve a narrower frame.

### SUMMARY

According to an aspect of the disclosure, there is provided a display device including: a display panel having a principal surface including a display area where an image is displayed and a non-display area surrounding the display area; a driver attached to the non-display area of the display panel, the driver having a quadrangular shape in planar view and having outer peripheral side parts including a first side part situated closest to the display area of the outer peripheral side parts; a first terminal provided in the non-display area of the display panel so as to overlap the driver; a first wire provided in the non-display area of the display panel, connected to the first terminal, and extended out from the first terminal toward the display area; a second terminal provided in the non-display area of the display panel so as to overlap the driver and be located further away from the display area than the first terminal and closer to an end of the first side part than the first terminal; a second wire provided in the non-display area of the display panel, connected to the second terminal, and extended out from the second terminal toward the display area; a first bump provided on the driver so as to project from a principal surface of the driver that faces the principal surface of the display panel and disposed to overlap the first terminal; a second bump provided on the driver so as to project from the principal surface of the driver that faces the principal surface of the display panel and disposed to overlap the second terminal; and a third bump provided on the driver so as to project from the principal surface of the driver that faces the principal surface of the display panel and located closer to the display area than the second bump and closer to the end of the first side part than the first bump, wherein the second wire includes an inclined portion extended out from the second terminal toward the end of the first side part and inclined with respect to the first side part, and the third bump has an oblong shape in planar view and has a longitudinal direction parallel with the inclined portion.

According to an aspect of the disclosure, there is provided a driver having a quadrangular shape in planar view and having outer peripheral side parts including a first side part, the driver including: a first bump provided so to project from a principal surface; a second bump provided so as to project from the principal surface and be located further away from the first side part than the first bump and closer to an end of the first side part than the first bump; and a third bump provided so as to project from the principal surface and be located closer to the first side part than the second bump and closer to the end of the first side part than the first bump, wherein the third bump has an oblong shape in planar view and has a longitudinal direction inclined with respect to the first side part.

### BRIEF DESCRIPTION OF THE DRAWINGS

FIG. 1 is a plan view of a liquid crystal panel, a driver, and a flexible substrate that constitute a liquid crystal display device according to Embodiment 1;

FIG. 2 is a schematic cross-sectional views of the liquid crystal panel, the driver, and the flexible substrate;

FIG. 3 is a circuit diagram showing an array of pixels in a display area of the liquid crystal panel;

FIG. 4 is a plan view showing a configuration of a region of placement of the driver on an array substrate constituting the liquid crystal panel;

FIG. 5 is a bottom view of the driver;

FIG. 6 is a cross-sectional view showing a state of connection between first terminals of the array substrate and first bumps of the driver;

FIG. 7 is a plan view showing a relationship between second terminals and second wires in the region of placement of the driver on the array substrate and second and third bumps;

FIG. 8 is a cross-sectional view of the array substrate and the driver as taken along line VIII-VIII in FIG. 5;

FIG. 9 is a cross-sectional view of the array substrate and the driver as taken along line IX-IX in FIG. 7;

FIG. 10 is a bottom view of a driver according to Embodiment 2;

FIG. 11 is a plan view showing a relationship between second terminals, second wires, third terminals, and third wires in a region of placement of the driver on an array substrate and second and third bumps;

FIG. 12 is a cross-sectional view of the array substrate and the driver as taken along line XII-XII in FIG. 11; and

FIG. 13 is a bottom view of a driver according to Embodiment 3.

### DESCRIPTION OF THE EMBODIMENTS

### Embodiment 1

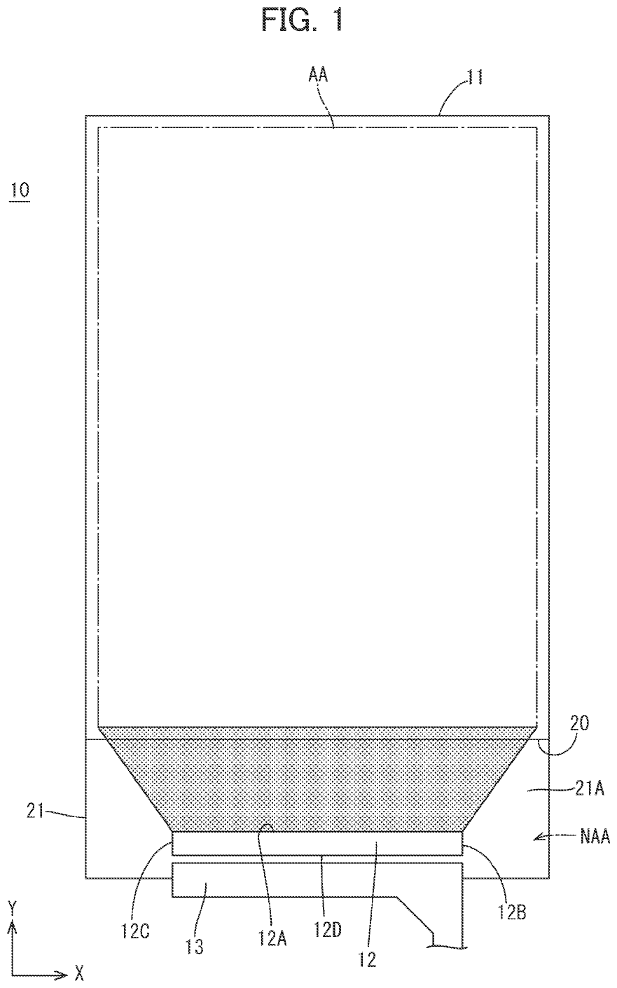

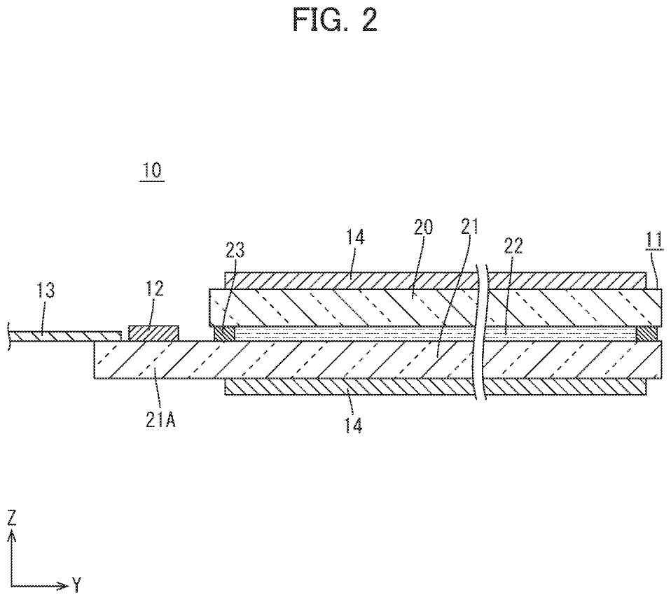

Embodiment 1 is described with reference to FIGS. 1 to 9. The present embodiment illustrates a liquid crystal display device (display device) 10. Note that some of the drawings show an X axis, a Y axis, and a Z axis and are drawn so that the direction of each axis is an identical direction in each drawing. Further, FIGS. 2, 6, 8, and 9 show upside front and downside back.

As shown in FIG. 1, the liquid crystal display device 10 includes at least a liquid crystal panel (display panel) 11 formed in the shape of a vertically long quadrangle and configured to display an image and a backlight device (lighting device) configured to illuminate the liquid crystal panel 11 with light for use in display. The backlight device is placed at the back of (behind) the liquid crystal panel 11. The backlight device includes a light source (such as an LED) configured to emit white light, an optical member configured to convert the light from the light source into planar light by imparting an optical effect to the light, or other components. The liquid crystal panel 11 has a principal surface a central portion of which serves as a display area AA where an image is displayed. On the other hand, a frame-shaped outer peripheral portion of the principal surface of the liquid crystal panel 11 that surrounds the display area AA serves as a non-display area NAA where no image is displayed.

The liquid crystal panel 11 is described with reference to FIGS. 1 and 2. As shown in FIGS. 1 and 2, the liquid crystal panel 11 includes two substrates 20 and 21 bonded to each other. A front one of the two substrates 20 and 21 is a counter substrate 20, and a back one of the two substrates 20 and 21 is an array substrate 21. The counter substrate 20 and the array substrate 21 each include a glass substrate and various types of films joined on top of each other on the inner surface of the glass substrate. Sandwiched between the two substrates 20 and 21 is a liquid crystal panel 22 containing liquid crystal molecules constituting a substance whose optical properties change in the presence of the application of an electric field. Interposed between outer peripheral ends of the two substrates 20 and 21 is a sealant 23 sealing the liquid crystal layer 22. The sealant 23 is formed in the shape of a quadrangular frame so as to surround the liquid crystal layer 22. Note that polarizing plates 14 are attached separately to each of the outer surfaces of the two substrates 20 and 21.

As shown in FIGS. 1 and 2, the counter substrate 20 has a long-side dimension that is shorter than a long-side dimension of the array substrate 21. The counter substrate 20 is bonded to the array substrate 21 so that a first end of the counter substrate 20 in a long-side direction (Y-axis direction) is aligned with a first end of the array substrate 21 in the long-side direction. Accordingly, a second end of the array substrate 21 in the long-side direction serves as an exposed area 21A exposed by protruding laterally with respect to the counter substrate 20. This exposed area 21A is entirely part of the non-display area NAA in which a driver 12 and a flexible substrate 13 are mounted for the supply of various types of signals.

The driver 12 is composed of an LSI chip having a driving circuit inside. The driver 12 is COG (chip on glass) mounted on the exposed area 21A of the array substrate 21. The driver 12 processes various types of signals that are transmitted by the flexible substrate 13. As shown in FIGS. 1 and 2, the driver 12 is placed adjacent to one side of the display area AA in the Y-axis direction, and is placed between the flexible substrate 13, which will be described next, and the display area AA. The driver 12 has the shape of a horizontally long quadrangle in planar view. The driver 12 has a long-side dimension that is smaller than a short-side dimension of the display area AA. The driver 12 has an outer shape constituted by outer peripheral side parts including two long side parts and two short side parts. Of the two long side parts of the driver 12, a long side part situated closer to the display area AA serves as a first side part 12A situated closest to the display area AA of the outer peripheral side parts. A first one of the two short side parts of the driver 12 serves as a second short side part 12B that is contiguous to the first side part 12. A second one of the two short side parts of the driver 12 serves as a third side part 12C that is contiguous to the first side part 12A. Of the two long side parts of the driver 12, a long side part that is far away from the display area AA serves as a fourth side part 12D that is furthest away from the display area AA of the outer peripheral side parts. The first side part 12A and the fourth side part 12D are parallel to an X-axis direction (first direction). The second side part 12B and the third side part 12C are parallel to the Y-axis direction (second direction). The driver 12 can supply various types of signal to lead wires 30 or other wires provided in the array substrate 21. Note that FIG. 1 illustrates the range of formation of the lead wires 30 in the array substrate 21 by half-tone dot meshing.

The flexible substrate 13 is configured such that a large number of wiring patterns are formed on a substrate composed of a synthetic resin material (such as polyimide resin) having insulation properties and flexibility. As shown in FIGS. 1 and 2, the flexible substrate 13 has a first end connected to the exposed area 21A of the array substrate 21 and a second end connected to an external circuit substrate (such as a control substrate). The flexible substrate 13 is connected to an end of the exposed area 21A opposite the display area AA behind the driver 12 in the Y-axis direction. The flexible substrate 13 has such a positional relationship with the driver 12 as to be placed at a spacing from the driver 12 in the Y-axis direction.

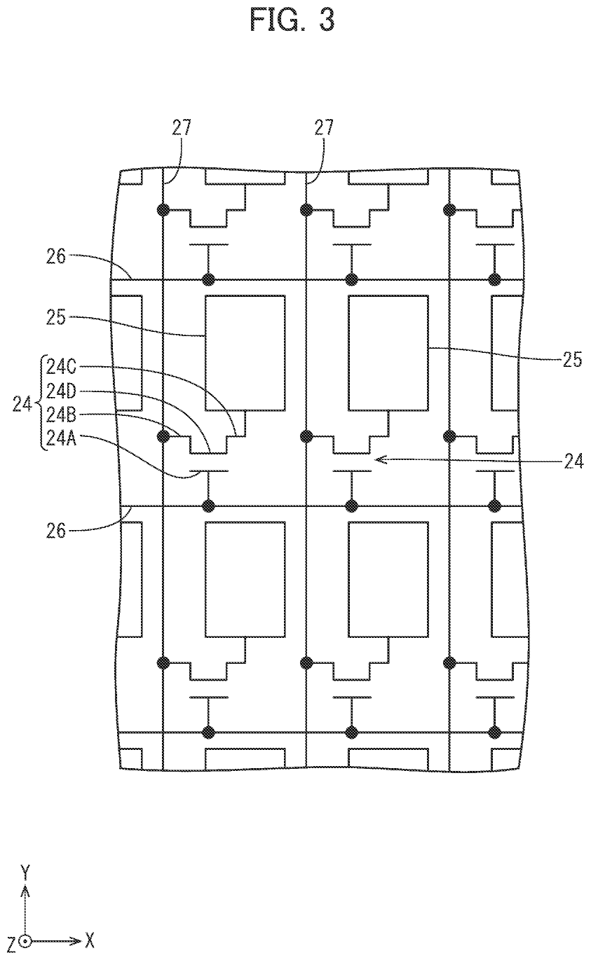

Next, a configuration of the display area AA in the array substrate 21 is described with reference to FIG. 3. As shown in FIG. 3, there are provided at least a TFT (thin-film transistor, switching element) 24 and a pixel electrode 25 on the inner surface of the array substrate 21 in the display area AA. A plurality of the TFTs 24 and a plurality of the pixel electrodes 25 are arranged at spacings in a matrix (in rows and columns) along the X-axis direction and the Y-axis direction. The TFT 24 and the pixel electrode 25 are surrounded by gate wires (scanning wires) 26 and source wires (pixel wires, signal wires) 27 that are orthogonal to (intersect) each other. The gate wires 26 extend along the X-axis direction. The source wires 27 extend along the Y-axis direction. The TFT 24 includes a gate electrode 24A connected to a gate wire 26, a source electrode 24B connected to a source wire 27, a drain electrode 24C connected to the pixel electrode 25, and a semiconductor component 24D connected to the source electrode 24B and the drain electrode 24C and composed of a semiconductor material. Moreover, the TFT 24 is driven in accordance with a scanning signal supplied to the gate electrode 24A via the gate wire 26. This causes a potential relating to an image signal (data signal) that is supplied to the source electrode 24B via the source wire 27 to be supplied to the drain electrode 24C via the semiconductor component 24D. This results in causing the pixel electrode 25 to be charged to the potential relating to the image signal. The pixel electrode 25 is placed in a region surrounded by the gate wires 26 and the source wires 27, and has, for example, a substantially rectangular shape in planar view. The pixel electrode 25 has such a relationship with a color filter as to overlap the color filter, and combines with the color filter to constitute a pixel. The color filter is placed in the display area AA of the counter substrate 20. The color filter takes on three colors, namely blue (B), green (G), and red (R). Note that alignment films for aligning the liquid crystal molecules contained in the liquid crystal layer 22 are provided separately on each of the innermost surfaces of the two substrates 20 and 21.

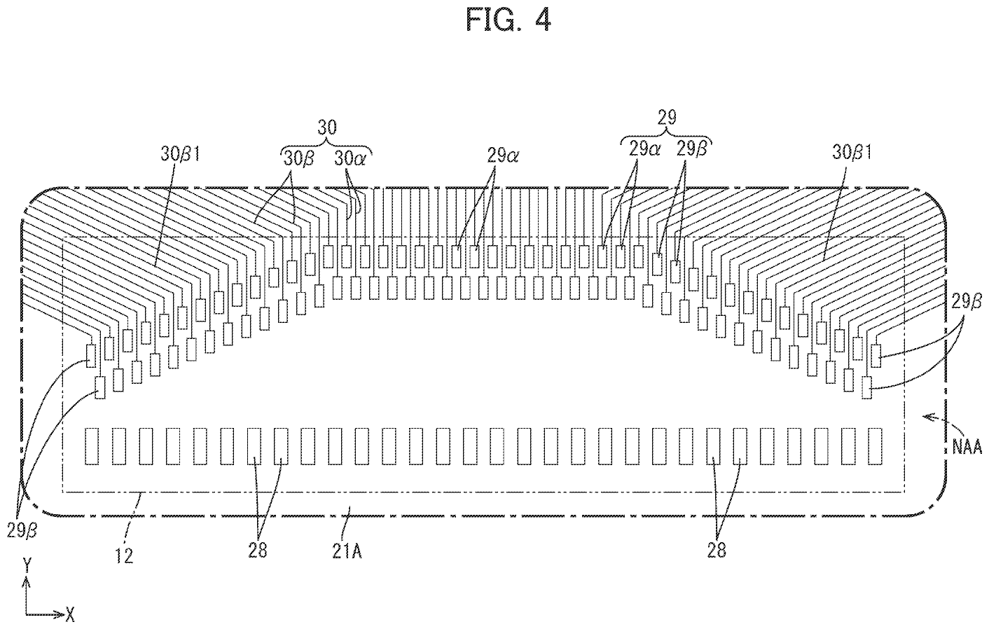

As shown in FIG. 4, wires and terminals through which to supply various types of signals (potentials) to the gate wires 26, the source wires 27, or other components are provided on the inner surface of the array substrate 21 in the exposed area 21A, which is the non-display area NAA. Provided in a region of the exposed area 21A that overlaps the driver 12 and in which the driver 12 is placed (mounted) are a plurality of terminals 28 and 29 that are connected to the driver 12 when the driver 12 is mounted on the exposed area 21A. Provided in a region of the exposed area 21A in which the flexible substrate 13 is placed are a plurality of terminals that are connected to the flexible substrate 13 when the flexible substrate 13 is mounted. Note that FIG. 4 uses chain double-dashed lines to illustrate the outer shape of the driver 12, which is mounted on the exposed area 21A.

As shown in FIG. 4, the plurality of terminals 28 and 29 include a plurality of input terminals 28 through which to input signals to the driver 12 and a plurality of output terminals 29 through which to receive signals outputted from the driver 12. The input terminals 28 and the output terminals 29 each have the shape of a vertically long quadrangle in planar view, and are placed so that their long sides are parallel to the Y-axis direction and their short sides are parallel to the X-axis direction. The input terminals 28 are larger in size and area than the output terminals 29 in planar view. The input terminals 28 are provided in a larger number than the output terminals 29. Note that signals that are outputted from the driver 12 to the output terminals 29 include at least image signals. Signals that are outputted from the driver 12 to the output terminals 29 may include common potential signals of a common potential, ground potential signals of a ground potential, or other signals as well as image signals.

As shown in FIG. 4, the input terminals 28 are located further away from the display area AA in the Y-axis direction than the output terminals 29. In other words, the input terminals 28 are located closer to the fourth side part 12D of the driver 12 than the output terminals 29. The plurality of input terminals 28 form a line in which they are linearly arranged at spacings along the X-axis direction. That is, both ends of each of the plurality of input terminals 28 in the Y-axis direction are substantially aligned with both ends of the other of the plurality of input terminals 28 in the Y-axis direction. The output terminals 29 are located closer to the display area AA in the Y-axis direction than the input terminals 28. In other words, the output terminals 29 are located closer to the first side part 12A of the driver 12 than the input terminals 28.

As shown in FIG. 4, the plurality of output terminals 29 form two lines placed at a spacing in the Y-axis direction. A plurality of output terminals 29 forming a first one of the two lines are located closer to the display area AA (first side part 12A) in the Y-axis direction than a plurality of output terminals 29 forming a second one of the two lines. The plurality of output terminals 29 forming the first line and the plurality of output terminals 29 forming the second line are displaced from each other in the X-axis direction so as to be in a staggered arrangement as a whole. The plurality of output terminals 29 include a plurality of first terminals 29α placed close to the center of the region of placement of the driver 12 in the X-axis direction and a plurality of second terminals 29β placed close to both ends of the region of placement of the driver 12 in the X-axis direction. The plurality of second terminals 29β are dispersedly placed so that the plurality of first terminals 29α are interposed between a plurality of second terminals 29β and a plurality of second terminals 29β on both sides of the plurality of first terminals 29α. The plurality of first terminals 29α form two lines, and the plurality of second terminals 29β form two lines.

As shown in FIG. 4, the plurality of first terminals 29α, which form two lines, are linearly arranged at spacings along the X-axis direction in each of the lines. That is, in each line, both ends of each of the plurality of first terminals 29α in the Y-axis direction are aligned with both ends of the other of the plurality of first terminals 29α in the Y-axis direction. The plurality of second terminals 29β, which form two lines, are linearly arranged at spacings along a direction (oblique direction) inclined with respect to both the X-axis direction the Y-axis direction in each of the lines. That is, in each line, both ends of each of the plurality of second terminals 29β differ in position from both ends of the other of the plurality of second terminals 29β in the Y-axis direction according to location in the X-axis direction. Specifically, a plurality of second terminals 29β forming either line are arranged from the center of the first side part 12A of the driver 12 toward ends of the first side part 12A in the X-axis direction and become gradually closer to the ends of the first side part 12A with distance from the display area AA in the Y-axis direction. Of the plurality of second terminals 29β forming either line, second terminals 29β located closest to the ends of the first side part 12A and furthest away from the first terminals 29α of the same line are located furthest away from the display area AA (first side part 12A) in the Y-axis direction and closest to the input terminals 28 (fourth side part 12D) in the Y-axis direction. Of the plurality of second terminals 29β forming either line, second terminals 29β located furthest away from the ends of the first side part 12A and closest to the first terminals 29α of the same line are located closest to the display area AA (first side part 12A) in the Y-axis direction and furthest away from the input terminals 28 (fourth side part 12D) in the Y-axis direction. Meanwhile, of a plurality of second terminals 29β forming a first one (in FIG. 4, an upper one) of the two lines, second terminals 29β located furthest away from the ends of the first side part 12A and closest to the first terminals 29α of the same line are located further away from the display area AA in the Y-axis direction than the first terminals 29α forming the first line. Similarly, of a plurality of second terminals 29β forming a second one (in FIG. 4, a lower one) of the two lines, second terminals 29β located furthest away from the ends of the first side part 12A and closest to the first terminals 29α of the same line are located further away from the display area AA in the Y-axis direction than the first terminals 29α forming the second line. That is, it can be said that of the plurality of first terminals 29α and the plurality of second terminals 29β belonging to the same line, the plurality of second terminals 29β are each located further away from the display area AA in the Y-axis direction than the first terminals 29α.

As shown in FIG. 4, the plurality of output terminals 29 include those which are connected to the lead wires 30, which are drawn from the source wires 27 of the display area AA. In the non-display area AA, the lead wires 30 are extended out from the region of placement of the driver 12 (or the output terminals 29 to which the lead wires 30 are connected) toward the display area AA. Note here that as shown in FIG. 1, the long-side dimension of the driver 12 is smaller than the short-side dimension of the display area AA. Accordingly, the lead wires 30 are routed so as to spread out in a fan-like form from the driver 12 toward the display area AA. Note that FIG. 4 omits to illustrate portions of the lead wires 30 situated close to the display area AA. The lead wires 30 have their first ends (situated close to the region of placement of the driver 12) connected to the output terminals 29 and their second ends (situated close to the display area AA) connected to ends of the source wires 27. As shown in FIG. 4, the plurality of lead wires 30 include a plurality of first wires 30α connected to the first terminals 29α and a plurality of second wires 30β connected to the second terminals 29β. The first wires 30α are connected to the first terminals 29α, which are located close to the center of the region of placement of the driver 12 in the X-axis direction, and source wires 27 located close to the center of the display area AA in the X-axis direction. On the other hand, the second wires 30β are connected to the second terminals 29β, which are located at both ends of the region of placement of the driver 12 in the X-axis direction, and source wires 27 located at both ends of the display area AA in the X-axis direction. Accordingly, the largest one of the distances in the X-axis direction between first ends of the second wires 30β and second ends of the second wires 30β is greater than the smallest one of the distances in the X-axis direction between first ends of the first wires 30α and second ends of the first wires 30α.

As shown in FIG. 4, the plurality of second wires 30β include inclined portions 30β1 each inclined with respect to the first side part 12A. Note that while some of the plurality of first wires 30α too include portions inclined with respect to the first side part 12, other first wires 30α do not include portions inclined with respect to the first side part 12A. The smallest one of the lengths of the inclined portions 30β1 of the second wires 30β is greater than the largest ones of the lengths of the portions of the first wires 30α inclined with respect to the first side part 12A. The inclined portions 30β1 are inclined at smaller angles with respect to the X-axis direction than with respect to the Y-axis direction.

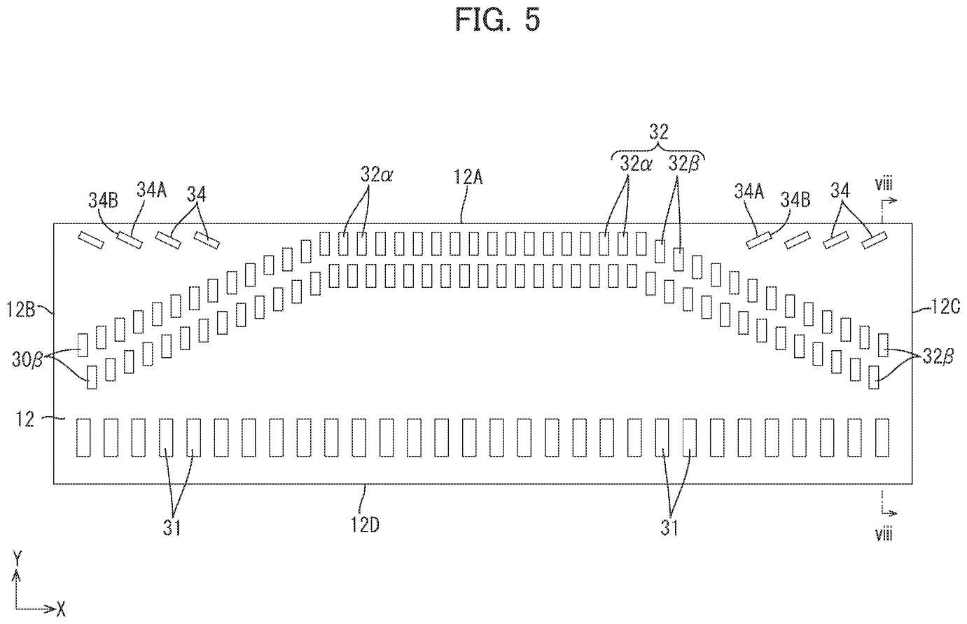

As shown in FIG. 5, a plurality of bumps 31 and 32 that are connected to the plurality of terminals 28 and 29 are provided on a principal surface (bottom surface) of the driver 12 that faces the array substrate 21. The bumps 31 and 32 are provided so as to project from the principal surface of the driver 12 toward the array substrate 21 in the Z-axis direction. The bumps 31 and 32 are connected to the circuit provided inside the driver 12. The plurality of bumps 31 and 32 are arranged on the bottom surface of the driver 12 so as to separately overlap each of the terminals 28 and 29 of the array substrate 21. The plurality of bumps 31 and 32 include a plurality of input bumps 31 through which to receive signals inputted from the array substrate 21 and a plurality of output bumps 32 through which to output signals to the array substrate 21. The input bumps 31 and the output bumps 32 each have the shape of a vertically long quadrangle in planar view, and are placed so that their long sides are parallel to the Y-axis direction and their short sides are parallel to the X-axis direction. The input bumps 31 are larger in size and area than the output bumps 32 in planar view. The input bumps 31 are provided in a larger number than the output bumps 32.

As shown in FIG. 5, the input bumps 31 are located further away from the first side part 12A, i.e. closer to the fourth side part 12D, in the Y-axis direction than the output bumps 32. The plurality of input bumps 31 form a line in which they are linearly arranged at spacings along the X-axis direction. That is, both ends of each of the plurality of input bumps 31 in the Y-axis direction are substantially aligned with both ends of the other of the plurality of input bumps 31 in the Y-axis direction. The output bumps 32 are located closer to the display area AA, i.e. closer to the first side part 12A, in the Y-axis direction than the input bumps 31.

As shown in FIG. 5, the plurality of output bumps 32 form two lines placed at a spacing in the Y-axis direction. A plurality of output bumps 32 forming a first one of the two lines are located closer to the first side part 12A in the Y-axis direction than a plurality of output bumps 32 forming a second one of the two lines. The plurality of output bumps 32 forming the first line and the plurality of output bumps 32 forming the second line are displaced from each other in the X-axis direction so as to be in a staggered arrangement as a whole. The plurality of output bumps 32 include a plurality of first output bumps (first bumps) 32α placed close to the center of the principal surface of the driver 12 in the X-axis direction and a plurality of second output bumps (second bumps) 32β placed close to both ends of the principal surface of the driver 12 in the X-axis direction. The plurality of second output bumps 32β are dispersedly placed so that the plurality of first output bumps 32α are interposed between a plurality of second output bumps 32β and a plurality of second output bumps 32β on both sides of the plurality of first output bumps 32α. The plurality of first output bumps 32α form two lines, and the plurality of second output bumps 32β form two lines.

As shown in FIG. 5, the plurality of first output bumps 32α, which form two lines, are linearly arranged at spacings along the X-axis direction in each of the lines. That is, in each line, both ends of each of the plurality of first output bumps 32α in the Y-axis direction are aligned with both ends of the other of the plurality of first output bumps 32α in the Y-axis direction. The plurality of second output bumps 32β, which form two lines, are linearly arranged at spacings along a direction (oblique direction) inclined with respect to both the X-axis direction the Y-axis direction in each of the lines. That is, in each line, both ends of each of the plurality of second output bumps 32β differ in position from both ends of the other of the plurality of second output bumps 32β in the Y-axis direction according to location in the X-axis direction. Specifically, a plurality of second output bumps 32β forming either line are arranged from the center of the first side part 12A toward the ends of the first side part 12A in the X-axis direction and become gradually closer to the ends of the first side part 12A with distance from the first side part 12A in the Y-axis direction. Of the plurality of second output bumps 32β forming either line, second output bumps 32β located closest to the ends of the first side part 12A and furthest away from the first output bumps 32α of the same line are located furthest away from the first side part 12A in the Y-axis direction and closest to the fourth side part 12D in the Y-axis direction. Of the plurality of second output bumps 32β forming either line, second output bumps 32β located furthest away from the ends of the first side part 12A and closest to the first output bumps 32α of the same line are located closest to the first side part 12A in the Y-axis direction and furthest away from the fourth side part 12D in the Y-axis direction. Meanwhile, of a plurality of second output bumps 32β forming a first one (in FIG. 5, an upper one) of the two lines, second output bumps 32β located furthest away from the ends of the first side part 12A and closest to the first output bumps 32α of the same line are located further away from the first side part 12A in the Y-axis direction than the first output bumps 32α forming the first line. Similarly, of a plurality of second output bumps 32β forming a second one (in FIG. 5, a lower one) of the two lines, second output bumps 32β located furthest away from the ends of the first side part 12A and closes to the first terminals 29α of the same line are located further away from the first side part 12A in the Y-axis direction than the first output bumps 32α forming the second line. That is, it can be said that of the plurality of first output bumps 32α and the plurality of second output bumps 32β belonging to the same line, the plurality of second output bumps 32β are each located further away from the first side part 12A in the Y-axis direction than the first output bumps 32α.

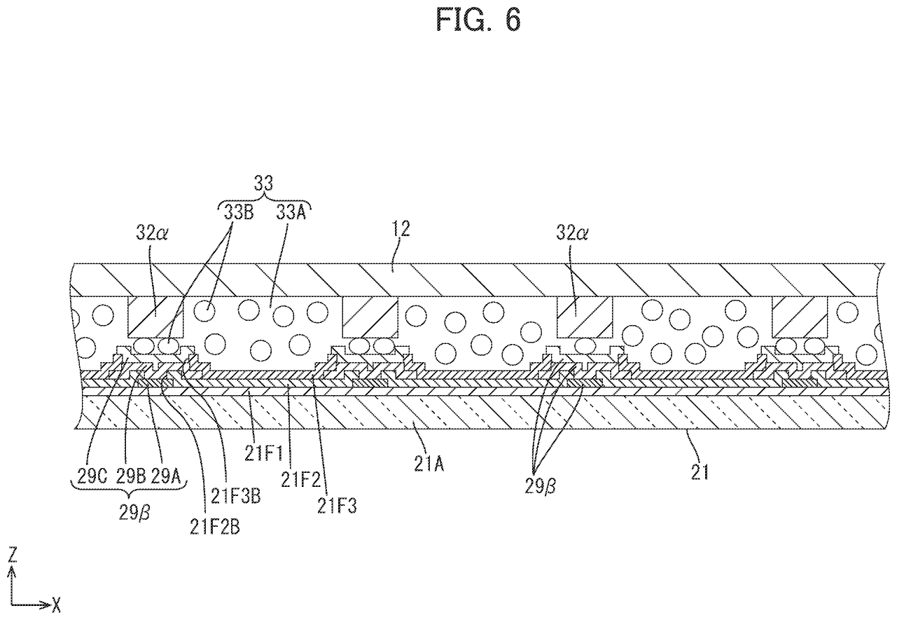

As shown in FIG. 6, the aforementioned terminals 28 and 29 and the aforementioned bumps 31 and 32 are connected to each other via an anisotropic conductive film (ACF) 33. The anisotropic conductive film 33 is described. The anisotropic conductive film 33 is a combination of a binder 33A composed of a thermosetting resin material and a large number of conducting particles 33B dispersed in the binder 33A. In mounting the driver 12, the anisotropic conductive film 33 and the driver 12 are set in the region of placement the driver 12 on the array substrate 21, and the driver 12 is then thermocompression bonded to the array substrate 21 with a load applied toward the array substrate 21. This causes the terminals 28 and 29 of the array substrate 21 and the bumps 31 and 32 of the driver 12 to be electrically connected to each other via the conducting particles 33B. Further, the binder 33A is thermally cured, so that the driver 12 is mechanically fixed to the array substrate 21.

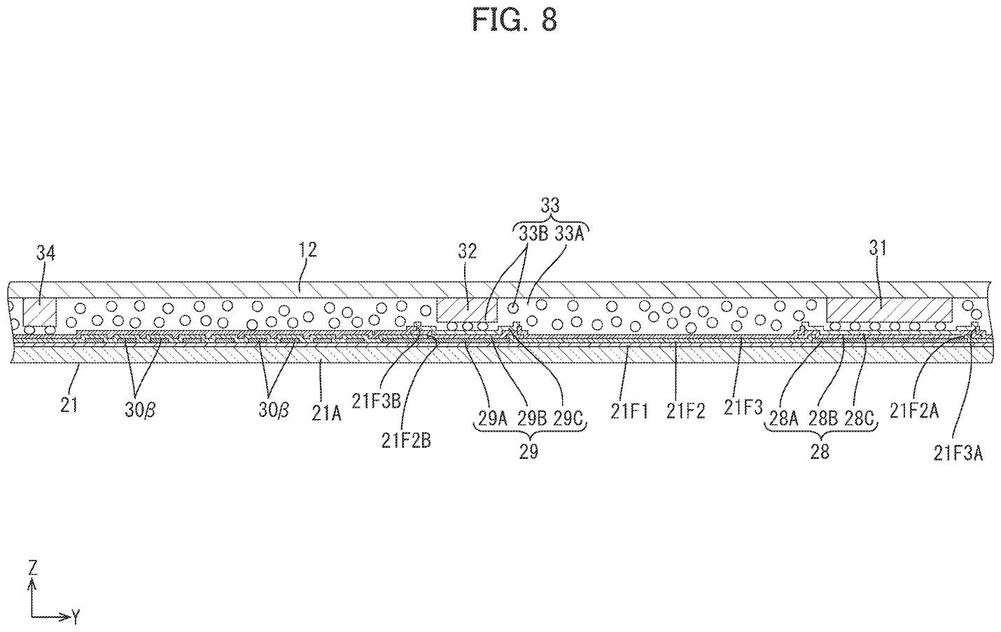

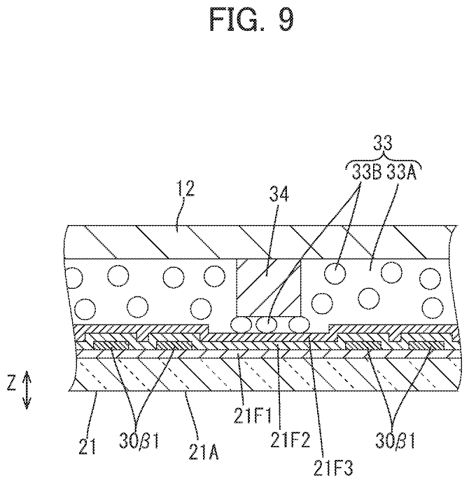

Configurations of the terminals 28 and 29 are described here with reference to FIGS. 8 and 9 together with the various types of films joined on top of each other on the inner surface of the array substrate 21. As shown in FIGS. 6, 8, and 9, the array substrate 21 includes at least a first insulating layer 21F1, a first metal film, a second insulating film 21F2, a second metal film, a third insulating film 21F3, and a transparent electrode film that are joined on top of each other in this order from a lower layer. Note that the array substrate 21 may include a semiconductor film or other films in addition to these films. The first metal film and the second metal film each have electrical conductivity and light blocking properties by being a single-layer film composed of one type of metal material selected from among copper, titanium, aluminum, molybdenum, tungsten, or other metals or a film stack or an alloy composed of different types of metal materials. The gate wires 26, the source wires 27, or other wires are constituted by the first metal film and the second metal film. The first insulating film 21F1, the second insulating film 21F2, and the third insulating film 21F3 are each composed of an inorganic material such as silicon nitride (SiNₓ) or silicon oxide (SiO₂). The transparent electrode film is composed of a transparent electrode material (such as ITO (indium tin oxide) or IZO (indicum zinc oxide)). The pixel electrode 25 or other electrodes are constituted by the transparent electrode film.

As shown in FIGS. 6, 8, and 9, the terminals 28 and 29 are stack structures including first terminal component parts 28A and 29A composed of the first metal film, second terminal component parts 28B and 29B composed of the second metal film, and third terminal component parts 28C and 29C composed of the transparent electrode film, respectively. In the second insulating layer 21F2, which is placed at a higher layer than the first terminal component parts 28A and 29A, openings 21F2A and 21F2B are formed so as to overlap the first terminal component parts 28A and 29A. The first terminal component parts 28A and 29A are exposed at the outside surface through the openings 21F2A and 21F2B and connected to the second terminal component parts 28B and 29B. In the third insulating layer 21F3, which is placed at a higher layer than the second terminal component parts 28B and 29B, openings 21F3A and 21F3B are formed so as to overlap the second terminal component parts 28B and 29B. The second terminal component parts 28B and 29B are exposed at the outside surface through the openings 21F3A and 21F3B and connected to the third terminal component parts 28C and 29C. The third terminal component parts 28C and 29C are entirely exposed at the outside surface. Since the third terminal component parts 28C and 29C, which are located at the uppermost layer in the terminals 28 and 29, are composed of the transparent electrode film, the first terminal component parts 28A and 29A and the second terminal component parts 28B and 29B, which are located at a lower layer than the third terminal component parts 28C and 29C and composed of the respective metal films, are resistant to corrosion. Further, as shown in FIG. 9, the lead wires 30 are composed of the first metal film. Accordingly, the lead wires 30 have their first ends joined directly to the first terminal component parts 29A of the output terminals 29. Note that although FIG. 9 representatively illustrates a cross-section configuration of second wires 30β, i.e. lead wires 30, the same applies to a cross-section configuration of first wires 30α.

As shown in FIG. 5, the driver 12 according to the present embodiment is provided with a third bump 34. The third bump 34 is provided so as to project from the principal surface (bottom surface) of the driver 12, which faces the array substrate 21, toward the array substrate 21 in the Z-axis direction. The third bump 34 is located closer to the first side part 12A (display area AA) than any of the second output bumps 32β. In particular, the third bump 34 is substantially identical in location in the Y-axis direction to the first output bumps 32α. The third bump 34 is located closer to an end of the first side part 12A than any of the first output bumps 32α. Thus, the third bump 34 is placed on the bottom surface of the driver 12 so as to be in a planimetrically triangular region surrounded by the plurality of second output bumps 32β forming the upper line of FIG. 5, the first side part 12A, and the second or third side part 12B or 12C. Accordingly, as shown in FIG. 8, the third bump 34 can satisfactorily support a portion of the driver 12 that is not supported by the first output bumps 32α or the second output bumps 32β. As a result, even when the driver 12 is mounted by being thermocompression bonded to the array substrate 21 with a load applied toward the array substrate 21, the driver 12 hardly suffers from deformation such as warpage due to the load. Suppression of deformation of the driver 12 makes it easy to keep good connecting conditions between the input bumps 31 and the input terminals 28 and between the output bumps 32 and the output terminals 29. This allows the driver 12 to have superior electrical connection reliability and superior mechanical fixation stability.

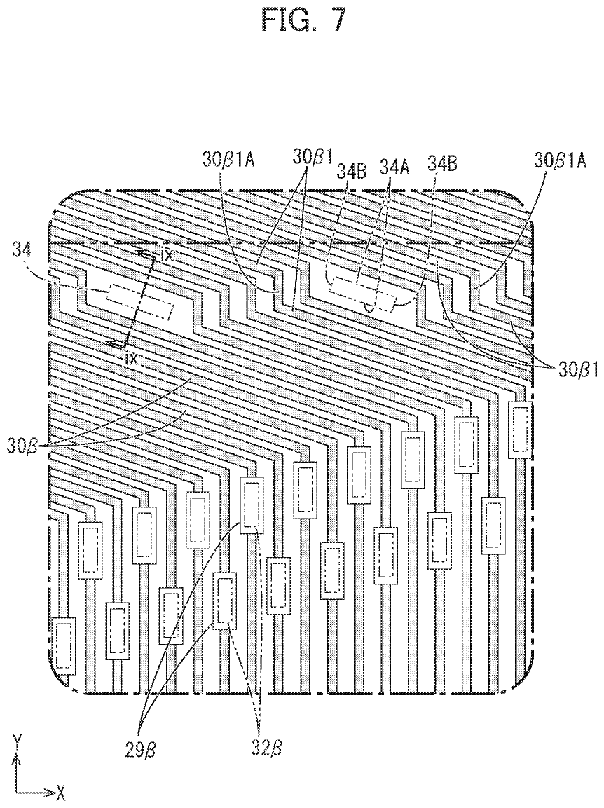

As shown in FIG. 7, the third bump 34 has the shape of a rectangle in planar view, and has two long sides 34A and two short sides 34B. The third bump 34 has its long sides 34A and its short sides 34B both inclined with respect to both the X-axis direction and the Y-axis direction. The third bump 34 is placed so that its long sides 34A are parallel to the inclined portions 30β1 of the second wires 30β. That is, the third bump 34, which has an oblong shape in planar view, is placed so that its longitudinal direction (i.e. a direction along the long sides 34A) is parallel with the inclined portions 30β1. In the present embodiment, the longitudinal direction of the third bump 34 is parallel with the inclined portions 30β1. The third bump 34 is disposed to have its longitudinal direction inclined at a smaller angle with respect to the X-axis direction than with respect to the Y-axis direction. The third bump 34 has its transverse direction (i.e. a direction along the short sides 34B) substantially orthogonal (intersecting) the inclined portions 30β1. The third bump 34 is disposed to have its transverse direction inclined at a smaller angle with respect to the Y-axis direction than with respect to the X-axis direction. Meanwhile, the plurality of second wires 30β include two second wires 301 between which the third bump 34 is interposed in the transverse direction. The spacing between the inclined portions 30β1 of the two second wires 301 between which the third bump 34 is interposed is greater than the spacing between the inclined portions 30β1 of two second wires 301 between which the third bump 34 is not interposed. Note that the inclined portions 30β1 are bent in the middle so as to circumvent the third bump 34, and include, as parts thereof (i.e. portions that faces the short sides 34B of the third bump 34), straight portions 30β1A extending substantially straight along the Y-axis direction. Further, the dimensions and areas of the long sides 34A of the third bump 34 are larger than the dimensions and areas of the long sides of an output bump 32.

According to such a configuration, the third bump 34 occupies a greater length in a direction parallel with the inclined portions 30β1 but occupies a smaller width in a direction orthogonal to the inclined portions 30β1 than does a third bump 34 having the shape of a square and having the same area as the aforementioned third bump 34. Accordingly, the spacing between the inclined portions 30β1 of the two second wires 30β between which the third bump 34 is interposed can be kept minimized. This makes it possible to densely arrange the second wires 30β, which include the inclined portions 30β1. Accordingly, the non-display area NAA of the liquid crystal panel 11 can be narrowed, so that a narrower frame can be achieved. Further, since the third bump 34 has an oblong shape, the area of the third bump 34 is sufficiently secured, so that a function of suppressing deformation of the driver 12 can be sufficiently brought about.

In the region of the exposed area 21A of the array substrate 21 in which the driver 12 is placed, as shown in FIGS. 7 and 9, neither the terminals 28 and 29 nor the lead wires 30 are present so as to overlap the third bump 34 of the driver 12. That is, the third bump 34 does not have an electrical function but has an exclusive function of mechanically supporting the driver 12. Accordingly, it can be said that the third bump 34 according to the present embodiment does not fall under the category of input bumps 31 or output bumps 32 but is a dummy bump. Thus, the third bump 34 is disposed not to overlap the second wires 30β. This makes it hard for the second wires 30β to, for example, become damaged due to the third bump 34 or to be short-circuited with the third bump 34.

As shown in FIGS. 5 and 7, a plurality of the third bumps 34 form a line in which they are arranged at spacings along the X-axis direction. Both ends of each of the plurality of third bumps 34 in the Y-axis direction are substantially aligned with both ends of the other of the plurality of third bumps 34 in the Y-axis direction. Even when the driver 12 is thermocompression bonded to the array substrate 21 with a load applied toward the array substrate 21, the driver 12 hardly suffers from deformation, as near-corner parts of the driver 12 including the first side part 12A are satisfactorily supported by the plurality of third bumps 34, which are arranged at spacings along the first side part 12A. This results in further superior connection reliability. The plurality of third bumps 34 are arrayed at greater spacings than the plurality of output bumps 32. A plurality of (in FIG. 7, five) second wires 30β are interposed between two third bumps 34 adjacent to each other at a spacing in the X-axis direction.

As shown in FIG. 5, the plurality of third bumps 34, which are arranged along the X-axis direction, include a third bump 34 located at an end of the first side part 12A. This third bump 34 is located closest to the second side part 12B or the third side part 12C. That is, the plurality of third bumps 34 include a third bump 34 on the bottom surface of the driver 12 so as to be in a corner position defined by the first side part 12A and the second or third side part 12B or 12C. Meanwhile, of the plurality of second output bumps 32β (second terminals 29β), a second output bump 32β located at the end of the first side part 12 is located closest to the fourth side part 12D (input bumps 31) and furthest away from the first side part 12A (display area AA) in comparison with the other second output bumps 32β. For this reason, the second terminal 29β is not placed in a corner of the driver 12, which has a quadrangular shape in planar view, particularly a near-corner part including the first side part 12A. In that respect, the plurality of third bumps 34 according to the present embodiment include a third bump 34 located at an end of the first side part 12A; therefore, as shown in FIG. 8, even when the driver 12 is thermocompression bonded to the array substrate 21, a near-corner part of the driver 12 including the first side part 12A is satisfactorily supported by the third bump 34. More specifically, the ends of the driver 12 in the X-axis direction are firmly supported at both ends in the Y-direction by third bumps 34 located at the ends of the first side part 12A and input bumps 31 and second output bumps 32β both located at the ends of the first side part 12A. As a result, even when the driver 12 is thermocompression bonded to the array substrate 21 with a load applied toward the array substrate 21, the driver 12 more hardly suffers from deformation. This brings about further superior connection reliability between the second terminals 29β and second output bumps 32β overlapping the second terminals 29β.

As described above, a liquid crystal display device (display device) 10 of the present embodiment includes: a liquid crystal panel (display panel) 11 having a principal surface including a display area AA where an image is displayed and a non-display area NAA surrounding the display area AA; a driver 12 attached to the non-display area NAA of the liquid crystal panel 11, the driver 12 having a quadrangular shape in planar view and having outer peripheral side parts including a first side part 12A situated closest to the display area AA of the outer peripheral side parts; a first terminal 29α provided in the non-display area NAA of the liquid crystal panel 11 so as to overlap the driver 12; a first wire 30α provided in the non-display area NAA of the liquid crystal panel 11, connected to the first terminal 29α, and extended out from the first terminal 29α toward the display area AA; a second terminal 29β provided in the non-display area NAA of the liquid crystal panel 11 so as to overlap the driver 12 and be located further away from the display area AA than the first terminal 29α and closer to an end of the first side part 12A than the first terminal 29α; a second wire 30β provided in the non-display area NAA of the liquid crystal panel 11, connected to the second terminal 29β, and extended out from the second terminal 29β toward the display area AA; a first output bump (first bump) 32α provided on the driver 12 so as to project from a principal surface of the driver 12 that faces the principal surface of the liquid crystal panel 11 and disposed to overlap the first terminal 29α; a second output bump (second bump) 32β provided on the driver 12 so as to project from the principal surface of the driver 12 that faces the principal surface of the liquid crystal panel 11 and disposed to overlap the second terminal 29β; and a third bump 34 provided on the driver 12 so as to project from the principal surface of the driver 12 that faces the principal surface of the liquid crystal panel 11 and located closer to the display area AA than the second output bump 32β and closer to the end of the first side part 12A than the first output bump 32α. The second wire 30β includes an inclined portion 30β1 extended out from the second terminal 29β toward the end of the first side part 12A and inclined with respect to the first side part 12A, and the third bump 34 has an oblong shape in planar view and has a longitudinal direction parallel with the inclined portion 30β1.

Attachment of the driver 12 to the non-display area NAA of the liquid crystal panel 11 causes the first output bump 32α and the second output bump 32β of the driver 12 to be connected to the first terminal 29α and the second terminal 29β of the liquid crystal panel 11. The second output bump 32β, which is disposed to overlap the second terminal 29β, is located further away from the display area AA than the first output bump 32α, which is disposed to overlap the first terminal 29α, and closer to the end of the first side part 12A than the first output bump 32α. On the other hand, the third bump 34 is located closer to the display area AA than the second output bump 32β and closer to the end of the first side part 12A than the first output bump 32α; therefore, even when the driver 12 is thermocompression bonded to the array substrate 21 with a load applied toward the array substrate 21, the third bump 34 can satisfactorily support a portion of the driver 12 that is not supported by the first output bump 32α or the second output bump 32β. This makes it hard for the driver 12 to suffer from deformation such as warpage, brings about superior connection reliability, and makes it possible to achieve narrowing of the non-display area NAA of the liquid crystal panel 11.

The second wire 30β is extended out from the second terminal 29β toward the display area AA. The inclined portion 30β1 of the second wire 30β is extended out from the second terminal 29β toward the end of the first side part 12A and inclined with respect to the first side part 12A. On the other hand, since the third bump 34 has an oblong shape in planar view and has a longitudinal direction parallel with the inclined portion 30β1 of the second wire 30β, the third bump 34 has its transverse direction intersecting the inclined portion 30β1. Based on such an intersection relationship, the third bump 34 occupies a sufficiently smaller width in the direction intersecting the inclined portion 30β1. This makes it possible to densely arrange second wires 30β including inclined portions 30β1, thus making it possible to give the liquid crystal panel 11 a narrower frame. Further, since the third bump 34 has an oblong shape, the area of the third bump 34 is sufficiently secured, so that a function of suppressing deformation of the driver 12 can be sufficiently brought about even when the driver 12 is thermocompression bonded to the array substrate 21 with a load applied toward the array substrate 21.

Further, a plurality of the second terminals 29β are arranged from a center of the first side part 12A toward the end of the first side part 12A and become gradually closer to the end of the first side part 12A with distance from the display area AA, and the third bump 34 is located at least at the end of the first side part 12A. Of the plurality of second terminals 29β, a second terminal 29β located at the end of the first side part 12A is located furthest away from the display area AA of the plurality of second terminals 29β. For this reason, the second terminal 29β is not placed in a corner of the driver 12, which has a quadrangular shape in planar view, particularly a near-corner part including the first side part 12A. On the other hand, the third bump 34 is located at least at the end of the first side part 12A; therefore, even when the driver 12 is thermocompression bonded to the array substrate 21 with a load applied toward the array substrate 21, a near-corner part of the driver 12 including the first side part 12A is satisfactorily supported by the third bump 34. This brings about superior connection reliability.

Further, a plurality of the third bumps 34 are arranged at spacings along the first side part 12A. Near-corner parts of the driver 12 including the first side part 12A are satisfactorily supported by the plurality of third bumps 34, which are arranged at spacings along the first side part 12A. This brings about superior connection reliability even when the driver 12 is thermocompression bonded to the array substrate 21 with a load applied toward the array substrate 21.

Further, the third bump 34 is disposed not to overlap the second wire 30β. This makes it hard for the second wires 30β to, for example, become damaged due to the third bump 34 or to be short-circuited with the third bump 34 even when the driver 12 is attached to the non-display area NAA of the liquid crystal panel 11.

Further, a driver 12 of the present embodiment has a quadrangular shape in planar view and has outer peripheral side parts including a first side part 12A, and the driver 12 includes: a first output bump 32α provided so to project from a principal surface; a second output bump 32β provided so as to project from the principal surface and be located further away from the first side part 12A than the first output bump 32α and closer to an end of the first side part 12A than the first bump 32α; and a third bump 34 provided so as to project from the principal surface and be located closer to the first side part 12A than the second output bump 32β and closer to the end of the first side part 12A than the first output bump 32α. The third bump 34 has an oblong shape in planar view and has a longitudinal direction inclined with respect to the first side part 12A.

With the driver 12 attached to an object of attachment (e.g. the liquid crystal panel 11), a portion of the driver 12 that is not supported by the first output bump 32α or the second output bump 32β can be satisfactorily supported by the third bump 34. This makes it hard for the driver 12 to suffer from deformation such as warpage and brings about superior connection reliability. In a case where the object of attachment is provided with a wire (e.g. a second wire 30β) and the wire includes an inclined portion 30β1 inclined with respect to the first side part 12A, placing the longitudinal direction of the third bump 34 parallel with the inclined portion 30β1 makes it possible to densely arrange second wires 30β. This makes it possible to give the object of attachment a narrower frame. Further, since the third bump 34 has an oblong shape, the area of the third bump 34 is sufficiently secured, so that a function of suppressing deformation of the driver 12 can be sufficiently brought about.

### Embodiment 2

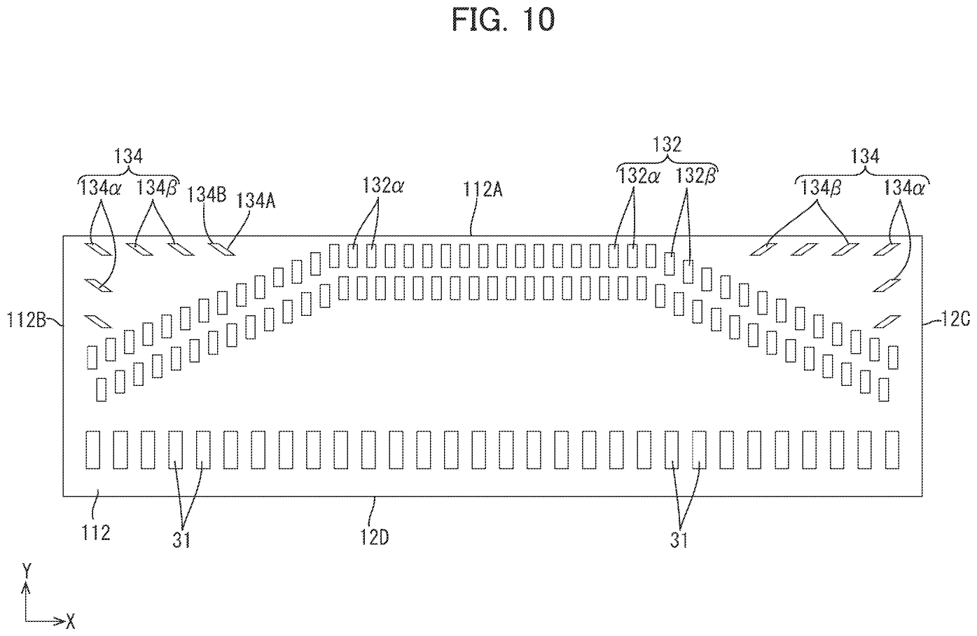

Embodiment 2 is described with reference to FIGS. 10 to 12. Embodiment 2 illustrates a case where the planar shape of a third bump 134 and the number of third bumps 134 that are provided are changed and the planar shape of a second wire 130β is changed. Note that a repeated description of structures, actions, and effects which are similar to those of Embodiment 1 is omitted.

As shown in FIG. 10, the third bump 134 according to the present embodiment has the shape a parallelogram shape in planar view. The third bump 134 is placed so that while its short sides 134B are parallel to the X-axis direction, its long sides 134A are inclined with respect to both the X-axis direction and the Y-axis direction. The third bump 134 includes a plurality of third bumps 134 arranged at spacings along the X-axis direction (first side part 112A) and a plurality of third bumps 134 arranged at spacings along the Y-axis direction (second and third side parts 112B and 112C) at ends of the first side part 112A. That is, the plurality of third bumps 134 are placed along corners of the bottom surface of a driver 112 and arrayed in the shape of letter L in planar view. The plurality of third bumps 134 include a plurality of third bumps 134 that are substantially identical in location in the Y-axis direction to first output bumps 132α and a plurality of third bumps 134 located at the ends of the first side part 112A in the X-axis direction.

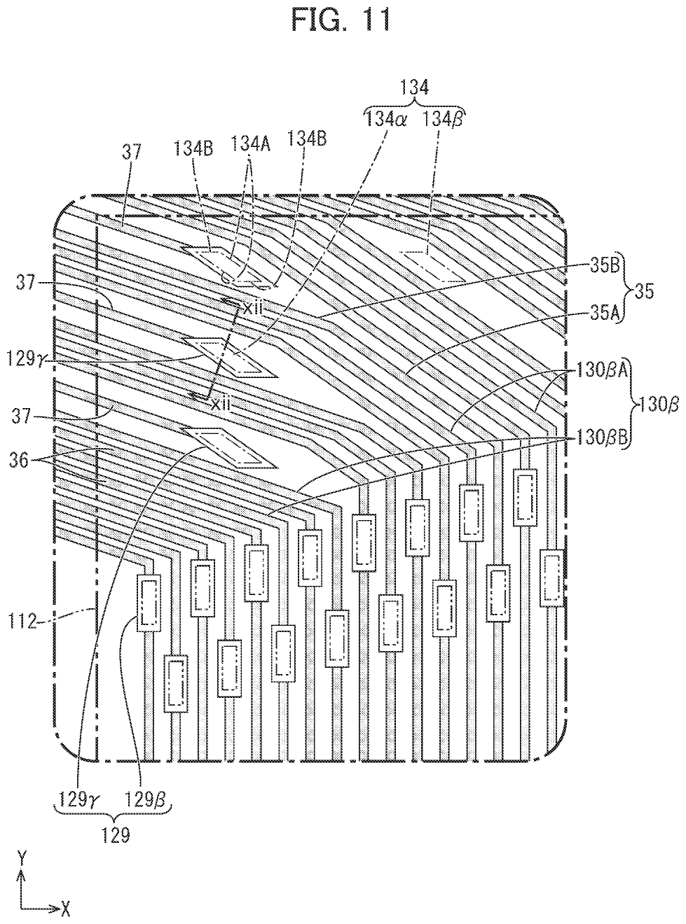

As shown in FIG. 11, a plurality of second wires 130β do not include the straight portions 30β1A (see FIG. 7) described above in Embodiment 1, and are routed through different paths according to an arrangement in the X-axis direction of second terminals 129β to which the second wires 130β are connected. Specifically, an inclined portion 35 of a second wire 130βA connected to a second terminal 129β placed close to the center in the X-axis direction changes in the middle from being inclined at one angle to being inclined at another angle with respect to the X-axis direction and the Y-axis direction. The inclined portion 35 of the second wire 130βA connected to the second terminal 129β placed close to the center in the X-axis direction includes a first inclined portion 35A that is close to the second terminal 129β and a second inclined portion 35B that is far away from the second terminal 129β and that is contiguous to the first inclined portion 35A. The second inclined portion 35B is inclined at a greater angle with respect to the Y-axis direction and inclined at a smaller angle with respect to the X-axis direction than the first inclined portion 35A. On the other hand, an inclined portion 36 of a second wire 130βB connected to a second terminal 129β placed close to an end in the X-axis direction is inclined at a given angle with respect to the X-axis direction and the Y-axis direction. The inclined portion 36 of the second wire 130βB connected to the second terminal 129β placed close to the end in the X-axis direction is inclined at the same angle as the second inclined portion 35 with respect to the X-axis direction and the Y-axis direction. As shown in FIG. 11, the third bump 134 is placed so that its long sides 134A are parallel to the second inclined portion 35B and the inclined portion 36. That is, the third bump 134, which has an oblong shape in planar view, is placed so that its longitudinal direction is parallel with the second inclined portion 35B and the inclined portion 36. In the present embodiment, the longitudinal direction of the third bump 134 is parallel with the second inclined portion 35B and the inclined portion 36. A plurality of the third bumps 134 include a third output bump 134α that is a type of output bump 132 that is connected to an output terminal 129 and a dummy bump 134β that is not connected to an output terminal 129. As shown in FIGS. 10 and 11, the third output bump 134α is located at an end of the first side part 112A in the X-axis direction, and three of these third output bumps 134α are arranged at spacings in the Y direction. The dummy bump 134β is substantially identical in location in the Y-axis direction to first output bumps 132α, and three of these dummy bumps 134β are arranged at spacings in the X direction. A plurality of the output terminals 129 include a plurality of third terminals 129γ provided in a region of placement of the driver 112 on an array substrate 121 and disposed to overlap the plurality of third output bumps 134α. Further, a plurality of lead wires 130 include a plurality of third wires 37 provided in the region of placement of the driver 112 on the array substrate 121 and connected to the plurality of third terminals 129γ. The third wires 37 are extended out in parallel with the second inclined portion 35B and the inclined portion 36.

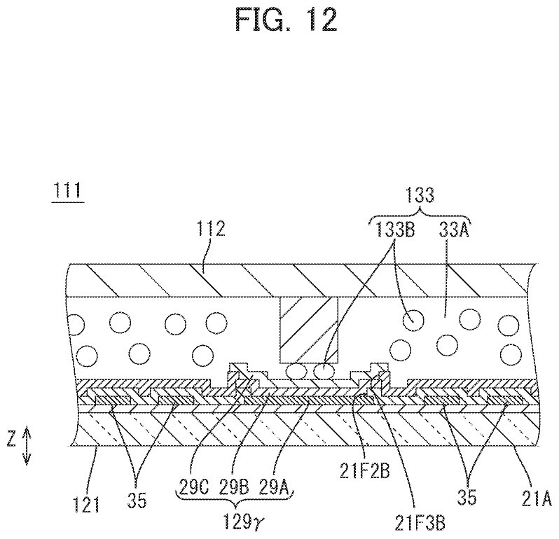

As shown in FIGS. 11 and 12, the third output bump 134α is electrically connected by conducting particles 133B of an anisotropic conductive film 133 to a third terminal 129γ overlapping the third output bump 134α, as is the case with the first output bumps 132α and second output bumps 132β. Accordingly, the third output bump 134α has both a deformation suppression function of suppressing deformation of the driver 112 and a signal transmission function of transmitting a signal to the third terminal 129γ. Note that the third terminal 129γ is similar in cross-section configuration to the input terminals, the first terminals, and the second terminals 129β described in Embodiment 1 (see FIGS. 6 and 8). Meanwhile, in the region of placement of the driver 112 on the array substrate 121, as shown in FIG. 11, neither the input terminals and the output terminals 129 nor the lead wires 130 are present so as to overlap the dummy bump 134β. That is, the dummy bump 134β does not have an electrical function but has an exclusive function of mechanically supporting the driver 112.

According to the present embodiment, as described above, the outer peripheral side parts of the driver 112 include a second side part 112B that is contiguous to the first side part 112A, and a plurality of the third bumps 134 are arranged at spacings along the second side part 112B. Near-corner parts of the driver 112 including the first side part 112A are satisfactorily supported by the plurality of third bumps 134, which are arranged at spacings along the second side part 112B. This brings about superior connection reliability even when the driver 112 is thermocompression bonded to the array substrate 121 with a load applied toward the array substrate 121.

Further, the liquid crystal display device 10 further includes a third terminal 129γ provided in the non-display area NAA of the liquid crystal panel 111 so as to overlap the driver 112 and be located closer to the display area AA than the second terminal 129β and closer to the end of the first side part 112A than the first terminal 29α (see FIG. 4), and the third bump 134 is disposed to overlap the third terminal 129γ. Attachment of the driver 112 to the non-display area NAA of the liquid crystal panel 111 causes the third output bump 134 of the driver 112 to be connected to the third terminal 129γ of the liquid crystal panel 111. This allows the third bump 134 to have both a function of suppressing deformation of the driver 112 and a function of transmitting a signal to the deriver 112, and makes it possible to achieve narrowing of the non-display area NAA of the liquid crystal panel 111.

### Embodiment 3

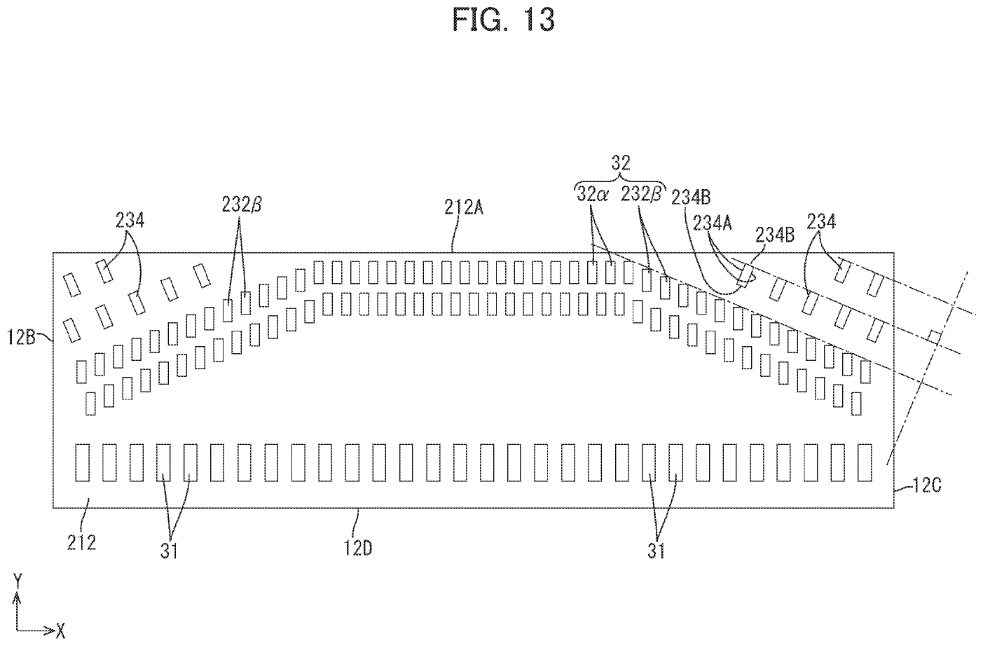

Embodiment 3 is described with reference to FIG. 13. Embodiment 3 illustrates a case where the planar shape of a third bump 234 and the number of third bumps 234 that are provided are changed from Embodiment 1. Note that a repeated description of structures, actions, and effects which are similar to those of Embodiment 1 is omitted.

As shown in FIG. 13, the third bump 234 according to the present embodiment is placed so that while its short sides 234B are parallel to a direction of arrangement of a plurality of second output bumps 232β (second terminals 29β), its long sides 234A are orthogonal to the direction of arrangement of the plurality of second output bumps 232β. The direction of arrangement of the plurality of second output bumps 232β coincides with a direction of arrangement of the plurality of second terminals 29β, which are connected to the plurality of second output bumps 232β (see FIG. 4). Note that FIG. 13 uses dot-and-dash lines to illustrate the direction of arrangement of the plurality of second terminals 29β, a direction of arrangement of a plurality of the third bumps 234, and a direction orthogonal to the direction of arrangement of the plurality of second output bumps 232β (third bumps 234). The short sides 243B of the third bump 234 are inclined at a smaller angle with respect to the X-axis direction than the short sides 34B of the third bump 34 described in Embodiment 1 are inclined with respect to the X-axis direction. The long sides 243A of the third bump 234 are inclined at a greater angle with respect to the X-axis direction than the long sides 34A of the third bump 34 described in Embodiment 1 are inclined with respect to the X-axis direction. A plurality of the third bumps 234 include a plurality of (in FIG. 13, four) third bumps 234 located far away from a corner of a driver 212 and close to second output bumps 232β and a plurality of (in FIG. 13, two) third bumps 234 located close to the corner of the driver 212 and far away from the second output bumps 232β.

When the driver 212 is mounted by being thermocompression bonded to the array substrate 21 with a load applied toward the array substrate 21, the driver 212 starts deforming at a point near the plurality of second terminals 29β and deforms to the greatest extent in a direction orthogonal to the direction of arrangement of the plurality of second terminals 29β. In that respect, when the longitudinal direction of the third bump 234, which has an oblong shape, is orthogonal to the direction of arrangement of the plurality of second terminals 29β, deformation of the driver 212 under load during thermocompression bonding can be effectively suppressed.

According to the present embodiment, as described above, a plurality of the second terminals 29β are arranged from a center of the first side part 212A toward the end of the first side part 212A and become gradually closer to the end of the first side part 212A with distance from the display area AA, and the third bump 134 placed so that the longitudinal direction is orthogonal to a direction of arrangement of the plurality of second terminals 29β. When the driver 212 is thermocompression bonded to the array substrate 21 with a load applied toward the array substrate 21, the driver 212 starts deforming at a point near the plurality of second terminals 29β and deforms to the greatest extent in a direction orthogonal to the direction of arrangement of the plurality of second terminals 29β. In that respect, since the longitudinal direction of the third bump 234, which has an oblong shape, is orthogonal to the direction of arrangement of the plurality of second terminals 29β, deformation of the driver 212 under load during thermocompression bonding can be effectively suppressed and narrowing of the non-display area NAA of the liquid crystal panel 11 can be achieved.

### Other Embodiments

The present disclosure is not limited to the embodiments described above with reference to the drawings. The following embodiments may be included in the technical scope of the present disclosure.
(1) The third bump 34, 134, or 234 may be disposed to overlap some of the second wires 30β or 130β. In that case, it is preferable that the third bump 34, 134, or 234 not overlap a plurality of second wires 30β or 130β but be disposed to overlap only one second wire 301 or 130β. This makes it possible to avoid a short circuit between second wires 301 or 301 even if the insulating film 21F2 or 21F3 sandwiched between the third bump 34, 134, or 234 and the second wire 301 or 1301 overlapping the third bump 34, 134, or 234 becomes damaged and the third bump 34, 134, or 234 and the second wire 301 or 1301 overlapping the third bump 34, 134, or 234 become electrically connected to each other.
(2) The long sides 34A, 134A, or 234A of the third bump 34, 134, or 234 may not be parallel to the inclined portions 30β1, 35, or 36 of the second wires 301 or 130β. For example, the long sides 34A, 134A, or 234A of the third bumps 34, 134, or 234 can be said to be “parallel” even if the long sides 34A, 134A, and 234A of the third bump 34, 134, or 234 are inclined at several degrees with respect to the inclined portions 30β1, 35, or 36 of the second wires 301 or 130β.
(3) The planar shapes and sizes of the third bumps 34, 134, and 234 can be appropriately changed to those not illustrated. For example, the planar shapes of the third bumps 34, 134, and 234 may be ellipses, ovals, or other shapes.
(4) The numbers of third bumps 34, 134, and 234 that are provided, planar arrangements of the third bumps 34, 134, and 234, spacings at which the third bumps 34, 134, and 234 are arrayed, or other features can be appropriately changed to those not illustrated.
(5) In Embodiment 2, all of the plurality of third bumps 134 may be third output bumps 134α. Alternatively, all of the plurality of third bumps 134 may be dummy bumps 134β.
(6) Specific arrays of the plurality of second terminals 29β and 129β can be appropriately changed to those not illustrated. For example, the plurality of second terminals 29β and 129β may be arrayed in an arc-like fashion in planar view.
(7) The numbers of first terminals 29α and second terminals 29β and 129β that are provided can be appropriately changed to those not illustrated.
(8) The liquid crystal panels 11 and 111 may have a touch panel function.
(9) The liquid crystal panels 11 and 111 may be replaced by other display panels (such as organic EL display panels).

The present disclosure contains subject matter related to that disclosed in Japanese Priority Patent Application JP 2022-097973 filed in the Japan Patent Office on Jun. 17, 2022, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
a display panel having a principal surface including a display area where an image is displayed and a non-display area surrounding the display area;
a driver attached to the non-display area of the display panel, the driver having a quadrangular shape in planar view and having outer peripheral side parts including a first side part situated closest to the display area of the outer peripheral side parts;
a first terminal provided in the non-display area of the display panel so as to overlap the driver;
a first wire provided in the non-display area of the display panel, connected to the first terminal, and extended out from the first terminal toward the display area;
a second terminal provided in the non-display area of the display panel so as to overlap the driver and be located further away from the display area than the first terminal and closer to an end of the first side part than the first terminal;
a second wire provided in the non-display area of the display panel, connected to the second terminal, and extended out from the second terminal toward the display area;
a first bump provided on the driver so as to project from a principal surface of the driver that faces the principal surface of the display panel and disposed to overlap the first terminal;
a second bump provided on the driver so as to project from the principal surface of the driver that faces the principal surface of the display panel and disposed to overlap the second terminal; and
a third bump provided on the driver so as to project from the principal surface of the driver that faces the principal surface of the display panel and located closer to the display area than the second bump and closer to the end of the first side part than the first bump,
wherein
the second wire includes an inclined portion extended out from the second terminal toward the end of the first side part and inclined with respect to the first side part, and
the third bump has an oblong shape in planar view and has a longitudinal direction parallel with the inclined portion.

2. The display device according to claim 1, wherein
a plurality of the second terminals are arranged from a center of the first side part toward the end of the first side part and become gradually closer to the end of the first side part with distance from the display area, and
the third bump is located at least at the end of the first side part.

3. The display device according to claim 2, wherein a plurality of the third bumps are arranged at spacings along the first side part.

4. The display device according to claim 2, wherein
the outer peripheral side parts of the driver include a second side part that is contiguous to the first side part, and
a plurality of the third bumps are arranged at spacings along the second side part.

5. The display device according to claim 1, wherein the third bump is disposed not to overlap the second wire.

6. The display device according to claim 1, further comprising a third terminal provided in the non-display area of the display panel so as to overlap the driver and be located closer to the display area than the second terminal and closer to the end of the first side part than the first terminal, and
the third bump is disposed to overlap the third terminal.

7. The display device according to claim 1, wherein
a plurality of the second terminals are arranged from a center of the first side part toward the end of the first side part and become gradually closer to the end of the first side part with distance from the display area, and
the third bump is placed so that the longitudinal direction is orthogonal to a direction of arrangement of the plurality of second terminals.

8. A driver having a quadrangular shape in planar view and having outer peripheral side parts including a first side part, the driver comprising:
a first bump provided so to project from a principal surface;
a second bump provided so as to project from the principal surface and be located further away from the first side part than the first bump and closer to an end of the first side part than the first bump; and
a third bump provided so as to project from the principal surface and be located closer to the first side part than the second bump and closer to the end of the first side part than the first bump,
wherein the third bump has an oblong shape in planar view and has a longitudinal direction inclined with respect to the first side part.
